(19) United States
(12) Patent Application Publication
(10) Pub. No.: US 2013/0099235 A1
(43) Pub. Date: Apr. 25, 2013

(54) SEMICONDUCTOR WAFER AND METHOD FOR MANUFACTURING STACK PACKAGE USING THE SAME

(71) Applicant: Kwon Whan HAN, Seoul (KR)

(72) Inventor: Kwon Whan HAN, Seoul (KR)

(73) Assignee: HYNIX SEMICONDUCTOR INC., Icheon-si (KR)

(21) Appl. No.: 13/367,788

(22) Filed: Feb. 7, 2012

(30) Foreign Application Priority Data
Oct. 21, 2011 (KR) 10-2011-108305

(51) Int. Cl. H01L 23/544; H01L 21/66

(52) U.S. Cl. 257/48; 438/17; 257/E21.531; 257/E23.179

(57) ABSTRACT

A semiconductor wafer includes a plurality of semiconductor chips having bonding pads; and a connection wiring line coupling the plurality of semiconductor chips such that a test signal, which is inputted through bonding pads of an arbitrary semiconductor chip among the plurality of semiconductor chips, is transmitted to bonding pads of other semiconductor chips among the plurality of semiconductor chips.

### CROSS-REFERENCE TO RELATED APPLICATIONS

The present application claims priority to Korean patent application number 10-2011-108305 filed on Oct. 21, 2011, which is incorporated herein by reference in its entirety.

### BACKGROUND OF THE INVENTION

The present invention relates to a semiconductor wafer and a method for manufacturing a stack package using the same.

Recently, a stack package, in which at least two semiconductor chips or at least two semiconductor packages are stacked using through-silicon vias (TSVs) to improve a data storage capacity and a data processing speed, has been developed.

In a stack package using through-silicon vias, since electrical connections are formed by the through-silicon vias, excellent electrical characteristics are obtained, an operating speed is increased, and it is possible to achieve miniaturization. However, it is difficult to test these stack packages because the through-silicon vias are made to a very small micro size scale.

In order to test the stack package using through-silicon vias, a method has been adopted in which test pads are formed on the through-silicon vias and test signals are applied to the through-silicon vias using the test pads. As the size of the through-silicon vias and the gap between the through-silicon vias decrease, it is becoming more difficult to form the test pads such that the test pads have a size larger than a basic size needed for an electrical test to be performed. Further, a physical stress is likely to be induced when probe needles or sockets are applied to the test pads. This physical stress may lead to an occurrence of a failure.

### BRIEF SUMMARY OF THE INVENTION

An embodiment of the present invention is directed to a semiconductor wafer which is suitable for testing and manufacturing a stack package with through-silicon vias.

Also, an embodiment of the present invention is directed to a method for manufacturing a stack package using the semiconductor wafer.

In one embodiment of the present invention, a semiconductor wafer includes: a plurality of semiconductor chips having bonding pads; and a connection wiring line coupling the plurality of semiconductor chips such that a test signal, which is inputted through bonding pads of an arbitrary semiconductor chip among the plurality of semiconductor chips, is transmitted to bonding pads of other semiconductor chips among the plurality of semiconductor chips.

The semiconductor wafer may further include scribe lanes formed between the semiconductor chips and dividing the plurality of semiconductor chips from one another. The connection wiring line may extend across the scribe lanes and may be cut when cutting along the scribe lanes.

Each of the plurality of semiconductor chips may include a control module associated with a semiconductor chip, where the control module is coupled with the connection wiring line and the bonding pads of the semiconductor chip and which transmits a test signal of the connection wiring line to the bonding pads.

The control module may include: a storage unit configured to store identity information of a semiconductor chip; a comparison unit configured to compare identity information included in the test signal and the identity information stored in the storage unit, and output an enable signal when both information is the same with each other; and a switching unit configured to be enabled by the is enable signal and transmit the test signal of the connection wiring line to the bonding pads. The identity information may be an identification code which is assigned to each semiconductor chip.

The control module may include: a counter configured to generate comparison coordinate values; a comparison unit configured to compare identity information included in the test signal and the identity information stored in the storage unit, and output an enable signal when the identity information included in the test signal matches the identity information stored in the storage unit; and a switching unit configured to be enabled by the enable signal and transmit the test signal to the bonding pads.

Counters of the semiconductor chips may generate different comparison coordinate values. For example, the counters of the respective semiconductor chips may generate different comparison coordinate values through generating comparison coordinate values by adding coordinate changing values to comparison coordinate values which are generated by counters of adjacent semiconductor chips.

In another embodiment of the present invention, a method for manufacturing a stack package includes: forming a semiconductor wafer including a plurality of semiconductor chips each comprising bonding pads and a connection wiring line which couples semiconductor chips of the plurality of semiconductor chips with one another such that a test signal, which is inputted through is bonding pads of an arbitrary semiconductor chip among the plurality of semiconductor chips, is transmitted to bonding pads of the other semiconductor chips among the plurality of semiconductor chips; selecting a semiconductor chip among the plurality of semiconductor chips formed on the semiconductor wafer; forming a semiconductor chip module by stacking a plurality of additional semiconductor chips, formed with through-silicon vias, on the selected semiconductor chip such that bonding pads of the selected semiconductor chip are connected with the through-silicon vias of the additional semiconductor chips; and testing the semiconductor chip module by applying a test signal to bonding pads of a semiconductor chip which is not the selected semiconductor chip.

Selecting the semiconductor chip among the plurality of semiconductor chips further comprises performing a test for each of the semiconductor chips on the semiconductor wafer and selecting a semiconductor chip which has passed the test.

Forming the semiconductor chip module further comprises: preparing a preliminary semiconductor chip module by stacking the additional semiconductor chip; testing the preliminary semiconductor chip module by applying a signal to the bonding pads of the unselected semiconductor chip; and returning to the action of stacking the additional semiconductor chip when the preliminary semiconductor chip has passed the action of testing.

After testing the preliminary semiconductor chip, the method may further include forming a reject mark on a preliminary semiconductor chip module which has not passed the action of testing so that an additional semiconductor chip is not stacked any more on the corresponding preliminary semiconductor chip module which has not passed the action of testing.

After testing the semiconductor chip module, the method may further include forming a reject mark on a semiconductor chip module which has not passed the testing so that the corresponding semiconductor chip is not used.

After testing the semiconductor chip module, the method may further include individualizing the semiconductor chip module by sawing the semiconductor wafer along peripheries of the selected semiconductor chip.

After individualizing the semiconductor chip module, the method may further include: mounting the semiconductor chip module having passed the testing, to a substrate formed with connection pads such that the through-silicon vias are connected with the connection pads; and forming a molding part to seal an upper surface of the substrate including the semiconductor chip module.

### BRIEF DESCRIPTION OF THE DRAWINGS

FIG. 1 is a plan view illustrating a semiconductor wafer in accordance with an embodiment of the present invention.

FIG. 2 is a block diagram illustrating a first example embodiment of the control module shown in FIG. 1.

FIG. 3 is a block diagram illustrating a second example embodiment of the control module shown in FIG. 1.

FIG. 4 is a view explaining an operation of the counter shown in FIG. 3.

FIGS. 5A to 5E are cross-sectional views illustrating a stack package that may be formed through a method of manufacturing a stack package in accordance with another embodiment of the present invention.

FIGS. 6A to 6G are cross-sectional views illustrating stack package that may be formed through a method for manufacturing the stack package in accordance with another embodiment of the present invention.

FIG. 7 is a perspective view illustrating an electronic apparatus having a stack package manufactured using the semiconductor wafer according to an embodiment of the present invention.

FIG. 8 is a block diagram showing an example of an electronic apparatus having a stack package manufactured using a semiconductor wafer according to an embodiment of the present invention.

### DESCRIPTION OF SPECIFIC EMBODIMENTS

Hereafter, specific embodiments of the present invention will be described in detail with reference to the accompanying drawings.

It is to be understood herein that the drawings are not necessarily to scale and in some instances proportions may have been exaggerated in order to more clearly depict certain features of embodiments of the invention.

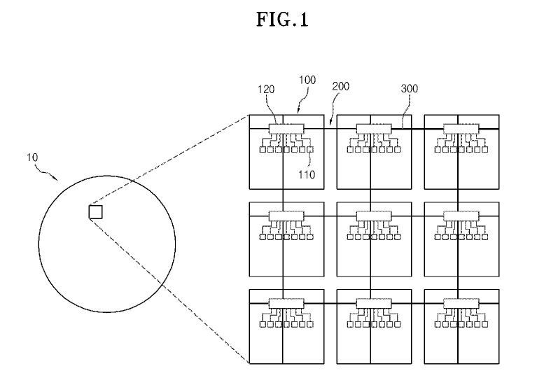

FIG. 1 is a plan view illustrating a semiconductor wafer in accordance with an embodiment of the present invention.

Referring to FIG. 1, a semiconductor wafer 10 in accordance with an embodiment of the present invention includes a plurality of semiconductor chips 100, scribe lanes 200 which divide the semiconductor chips 100, and a connection wiring line 300.

The plurality of semiconductor chips 100 are arranged in a row-column matrix with the scribe lanes 200 formed therebetween.

Each of the semiconductor chips 100 includes bonding pads 110 and a control module 120.

A plurality of bonding pads 110 may be arranged along a center portion of each semiconductor chip 100. The bonding pads 110 include a test chip selection pad to which identity information of a semiconductor chip to be tested is inputted. The bonding pads 110 may also include a data pad to which a data signal is inputted, a power supply pad to which a power supply voltage is inputted, and a control pad to which a control signal is inputted.

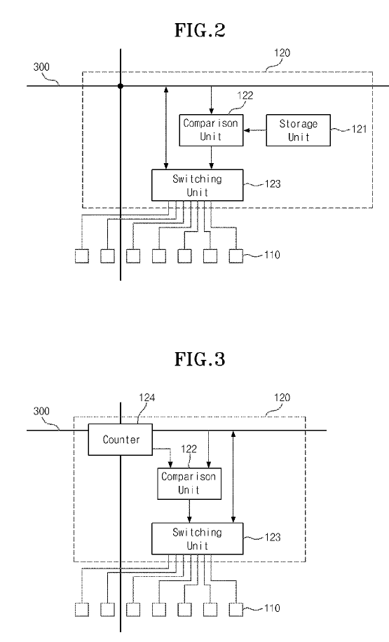

The control module 120 is coupled between the connection wiring line 300 and the bonding pads 110 and transmits a test signal of the connection wiring line 300 to the bonding pads 110. Further, the control module 120 transmits a test signal which is inputted to the bonding pads 110 from an external test equipment, to the connection wiring line 300. The configuration and operation of the control module 120 will be described later in detail with reference to FIGS. 2 to 4.

The connection wiring line 300 couples the semiconductor chips 100 with one another such that a test signal, which is inputted through the bonding pads of an arbitrary semiconductor chip 100 among the semiconductor chips 100, may be transmitted to bonding pads of the other semiconductor chips. In the present embodiment, the connection wiring line 300 extends across the scribe lanes and couples adjoined semiconductor chips 100 with the scribe lanes 200 formed therebetween. While not shown in a drawing, when cutting the scribe lanes 200 after a test is completed, the connection wiring line 300 may be cut when cutting or sawing along the scribe lanes 200.

FIG. 2 is a block diagram illustrating a first example embodiment of the control module shown in FIG. 1.

Referring to FIG. 2, the first example embodiment of the control module 120 includes a storage unit 121, a comparison unit 122, and a switching unit 123.

The storage unit 121 stores an identification code assigned to each semiconductor chip 110 as chip identify information. That is to say, an inherent identification code is assigned to each semiconductor chip 100 and is stored in the storage unit 121 of each semiconductor chip 100. A semiconductor chip from among the plurality of semiconductor chips 100 may be selected for testing using the assigned identification code.

The comparison unit 122 compares the identification code included in the test signal of the connection wiring line 300 with the identification code stored in the storage unit 121, and outputs an enable signal when the identification codes match.

The switching unit 123 is coupled with the connection wiring line 300 and the bonding pads 110. The switching unit 123 electrically connects the connection wiring line 300 with the bonding pads 110. Thus, when an enable signal is inputted from the comparison unit 122 the test signal of the connection wiring line 300 may be transmitted to the bonding pads 110. Further, the switching unit 123 electrically connects the bonding pads 110 with the connection wiring line 300. Thus, when a test signal is inputted to the bonding pads 110 from the external test equipment the test signal may be transmitted to the connection wiring line 300.

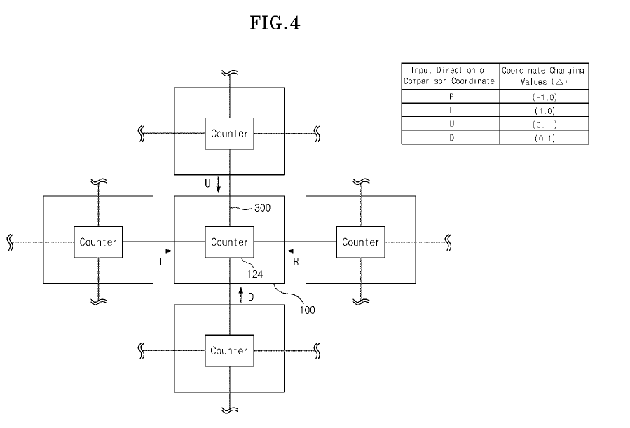

FIG. 3 is a block diagram illustrating a second example embodiment of the control module shown in FIG. 1. FIG. 4 is a view explaining an operation of a counter shown in FIG. 3.

Referring to FIG. 3, the second example embodiment of the control module 120 includes a counter 124, a comparison unit 122 and a switching unit 123.

The second example embodiment of the control module 120 includes the counter 124 for generating comparison coordinate values. The counter 124 may be used instead of the storage unit 121 of the first example embodiment of the control module 120.

Counters 124 of the semiconductor chips 100 generate different comparison coordinate values. In the present embodiment, a semiconductor chip may be selected for testing from among the plurality of semiconductor chips 100 using the comparison coordinate values of a respective semiconductor chip 100 as chip identity information.

Referring to FIGS. 3 and 4, each counter 124 is coupled with the counters of the other semiconductor chips 100 through the connection wiring line 300. In the present embodiment, the counter 124 is coupled with the counters of four adjacent semiconductor chips 100 through the connection wiring line 300.

The comparison coordinate values generated by the counters of adjacent semiconductor chips are inputted to the counter 124. The counter 124 generates comparison coordinate values by adding coordinate changing values A to the comparison coordinate values inputted from the counters of the adjacent semiconductor chips.

In detail, when the comparison coordinate values generated by the counter of the semiconductor chip positioned on a right side (case R) when viewed from the position of the semiconductor chip including the counter 124 are inputted, the counter 124 generates comparison coordinate values by adding coordinate changing values of (−1, 0) to the inputted comparison coordinate values. Unlike this, when the comparison coordinate values generated by the counter of the semiconductor chip positioned on a left side (case L) are inputted, the counter 124 generates comparison coordinate values by adding coordinate changing values of (1, 0) to the inputted comparison coordinate values. Also, when the comparison coordinate values generated by the counter of the semiconductor chip positioned on an upper side (case U) are inputted, the counter 124 generates comparison coordinate values by adding coordinate changing values of (0, −1) to the inputted comparison coordinate values. When the comparison coordinate values generated by the counter of the semiconductor chip positioned on a lower side (case D) are inputted, the counter 124 generates comparison coordinate values by adding coordinate changing values of (0, 1) to the inputted comparison coordinate values.

The comparison coordinate values generated in this way are outputted to adjacent semiconductor chips. Accordingly, the counters of the semiconductor chips 100 generate different comparison coordinate values according to their positions.

Referring again to FIG. 3, the comparison unit 122 compares the comparison coordinate values included in the test signal received from the connection wiring line 300 with the comparison coordinate values outputted from the counter 124, and outputs an enable signal when the coordinate values correspond to and/or match each other.

The switching unit 123 is coupled with the connection wiring line 300 and the bonding pads 110. The switching unit 123 electrically connects the connection wiring line 300 with the bonding pads 110. Thus, when an enable signal is inputted from the comparison unit 122, the test signal from the connection wiring line 300 may be transmitted to the bonding pads 110. Further, the switching unit 123 electrically connects the bonding pads 110 with the connection wiring line 300 when a test signal is inputted to the bonding pads 110 from the external test equipment. Thus, the test signal may be transmitted to the connection wiring line 300.

The semiconductor wafer 10 described above is suitable for testing and manufacturing a stack package with through-silicon vias.

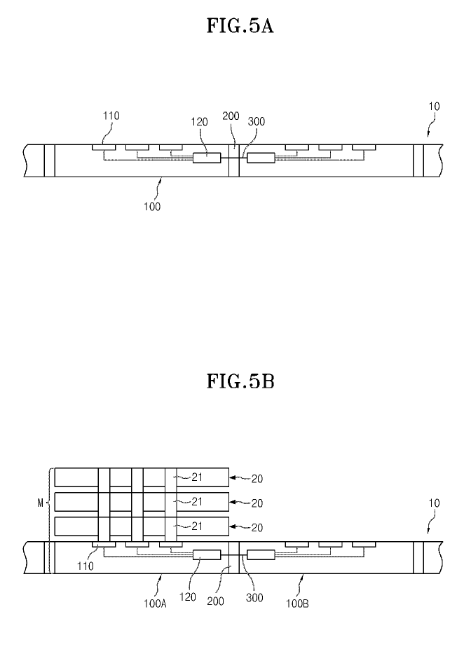

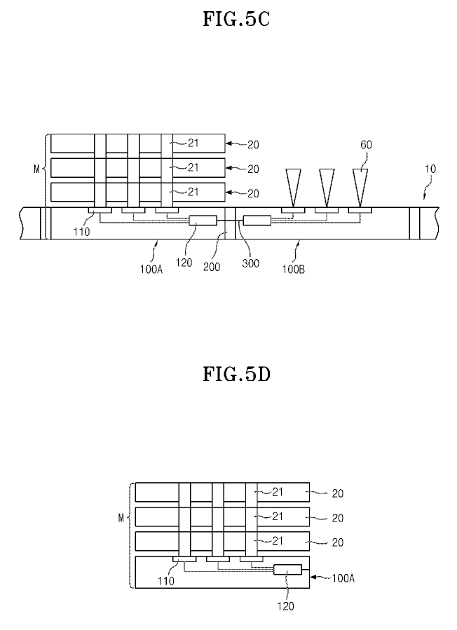

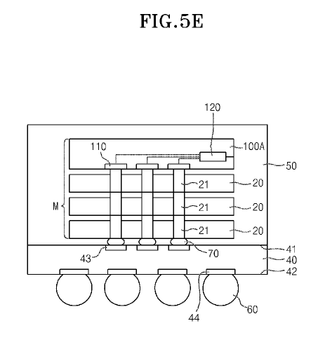

FIGS. 5A to 5E are cross-sectional views illustrating a stack package that may be formed through a method for manufacture in accordance with another embodiment of the present invention.

Referring to FIG. 5A, a semiconductor wafer 10 is formed.

The semiconductor wafer 10 has the same configuration as the semiconductor wafer described above with reference to FIGS. 1 to 4. Therefore, repeated descriptions for the same component parts will be omitted herein, and the same terms and the same reference numerals will be used to refer to the same component parts.

Referring to FIG. 5B, a semiconductor chip 100A is selected from among semiconductor chips on the semiconductor wafer 10 and a plurality of additional semiconductor chips 20. The additional semiconductor chips 20 may be formed with through-silicon vias 21 and are stacked over the semiconductor chip 100A such that the through-silicon vias 21 of the additional semiconductor chips 20 are connected with bonding pads 110 of the semiconductor chip 100A. In this way, a semiconductor chip module M is formed from the additional semiconductor chips 20 and the semiconductor chip 100A.

In FIG. 5B, the reference numeral 100A designates a selected semiconductor chip, and the reference numeral 100B designates an unselected semiconductor chip.

In a method for selecting the semiconductor chip, for example, by performing an EDS (electrical die sorting) test for each of a plurality of semiconductor chips 100 which are formed on the semiconductor wafer 10, good quality semiconductor chips which have passed a test may be selected, and bad quality semiconductor chips which have not passed the test may not be selected. Additional semiconductor chips 20 which have passed the EDS test and which have been individualized through a sawing process may be used as part of a semiconductor package.

While one semiconductor chip module M is illustrated in the drawing, since the single semiconductor wafer 10 generally has a number of semiconductor chips which have passed the EDS test, a plurality of semiconductor chip modules M are formed on the semiconductor wafer 10.

Referring to FIG. 5C, the semiconductor chip module M is tested by applying a test signal from the test equipment to the bonding pads 110 of the unselected semiconductor chip 1006. The test signal may be applied with a probe needle or socket 60 of test equipment brought into contact with the bonding pads 110 of the unselected semiconductor chip 1006.

The test signal applied to the bonding pads 110 of the unselected semiconductor chip 100B is loaded on the connection wiring line 300. The test signal includes the identity information of the semiconductor chip 100A included in the semiconductor chip module M which is to be tested. The semiconductor chips 100A and 100B on the semiconductor wafer 10 compare the identity information included in the test signal with their identity information, and electrically connect the connection wiring line 300 with their bonding pads 110 when the identity information of either semiconductor chip 100A or 100B matches the identity information of the test signal. Thereafter, the test signal is transmitted to the through-silicon vias 21 which are connected to the bonding pads 110 the semiconductor chip 100A or 100B that matched the identity information of the test signal. Accordingly, a semiconductor chip module M to be tested may be selectively tested among the plurality of semiconductor chip modules M.

While not shown, in order to prevent a semiconductor chip module M having not passed the test from being used in the manufacture of a package, a reject mark may be formed on the corresponding semiconductor chip module M.

Referring to FIG. 5D, the semiconductor chip module M is individualized by sawing the semiconductor wafer 100 along scribe lanes 200. Accordingly, the selected semiconductor chip module M may be individualized by sawing around peripheries of the selected semiconductor chip 100A.

Referring to FIG. 5E, the semiconductor chip module M having passed the test is mounted to a substrate 40 which is formed with connection pads 43 on an upper surface 41 thereof, in such a manner that the through-silicon vias 21 are connected with the connection pads 43. A molding part 50 is formed to mold an upper surface 41 of the substrate 40 including the semiconductor chip module M. By mounting external connection terminals 60 such as solder balls to ball lands 44 which are formed on a lower surface 42 of the substrate 40, a stack package is completed. The is reference numeral 70 designates connection members which electrically connect the through-silicon vias 21 of the semiconductor chip module M with the connection pads 43 of the substrate 40.

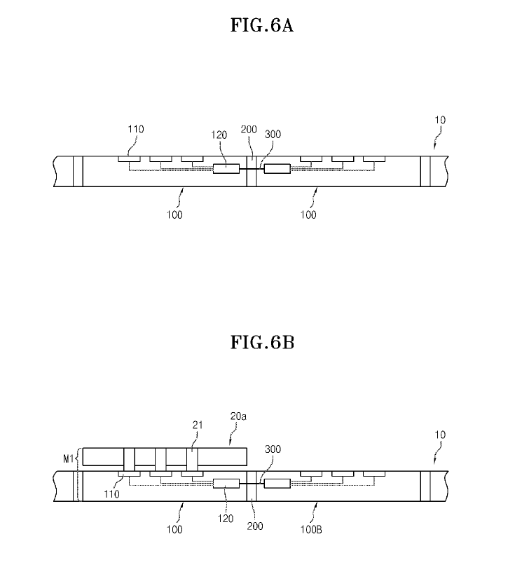

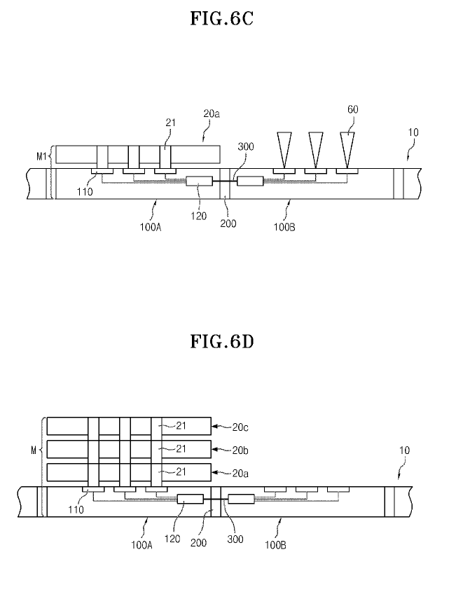

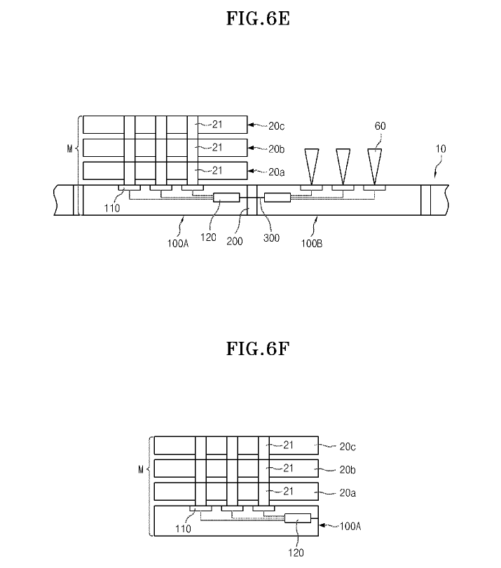

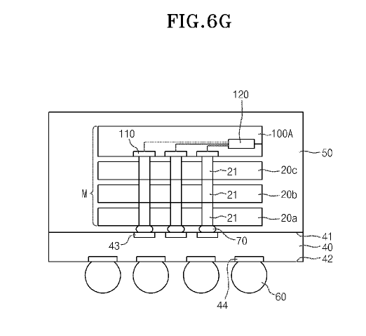

FIGS. 6A to 6G are cross-sectional views illustrates a stack package that may be formed using a method for manufacture in accordance with another embodiment of the present invention.

Unlike the aforementioned embodiment in which the test is performed after the semiconductor chip module M is formed by stacking all the plurality of additional semiconductor chips 20, in the present embodiment, a test is performed each time one additional semiconductor chip 20a is stacked first. Hence, the stack package manufacturing method in accordance with the second embodiment of the present invention is substantially the same as the stack package manufacturing method in accordance with the aforementioned embodiment except that a test process is added between processes for stacking respective additional semiconductor chips 20. Therefore, the same terms and the same reference numerals will be used to refer to the same component parts.

Referring to FIG. 6A, a semiconductor wafer 10 is formed.

The semiconductor wafer 10 has the same configuration as the semiconductor wafer described above with reference to FIGS. 1 to 4. Therefore, repeated descriptions for the same component parts will be omitted herein, and the same terms and the same reference numerals will be used to refer to the same component parts.

Referring to FIG. 6B, a semiconductor chip 100A is selected from among semiconductor chips on the semiconductor wafer 10, and an additional semiconductor chip 20a, which is formed with through-silicon vias 21, is stacked over the selected semiconductor chip 100A such that the through-silicon vias 21 of the additional semiconductor chip 20a are connected with bonding pads 110 of the selected semiconductor chip 100A. In this way, a preliminary semiconductor chip module M1 is formed.

In FIG. 6B, the reference numeral 100A designates the selected semiconductor chip, and the reference numeral 100B designates an unselected semiconductor chip.

In a method for selecting the semiconductor chip, for example, by performing an EDS (electrical die sorting) test for each of a plurality of semiconductor chips 100 which are formed on the semiconductor wafer 10, good quality semiconductor chips which have passed the test may be selected, and bad quality semiconductor chips which have not passed the test may not be selected. Additional semiconductor chip 20a which has passed the EDS test and which has been individualized through a sawing process may be used in a semiconductor package comprised of, for example, semiconductor chips 20a, 20b and 20c.

While one preliminary semiconductor chip module M1 is illustrated in the drawing, since the single semiconductor wafer 10 generally has a number of semiconductor chips which have passed the EDS test (and are thus selected), a plurality of preliminary semiconductor chip modules M1 are formed on the semiconductor wafer 10.

Referring to FIG. 6C, when the probe needles or sockets 60 of a test equipment are brought into contact with the bonding pads 110 of the unselected semiconductor chip 1006, the preliminary semiconductor chip module M1 is tested by applying a test signal from the test equipment to the bonding pads 110 of the unselected semiconductor chip 1006.

The test signal applied to the bonding pads 110 of the unselected semiconductor chip 100B is loaded on the connection wiring line 300. The test signal includes identity information of the semiconductor chip 100A included in the preliminary semiconductor chip module M1 which is to be tested from among the plurality of preliminary semiconductor chip modules Ml. The semiconductor chips on the semiconductor wafer 10 compare the identity information included in the test signal with their identity information, and electrically connect the connection wiring line 300 with their bonding pads 110 when their identity information matches the identity information of the test signal. Thereafter, the test signal is transmitted to the through-silicon vias 21 which are connected to the bonding pads 110 of the semiconductor chip receiving the test signal. Accordingly, the preliminary semiconductor chip module M1 to be tested may be selectively tested among the plurality of preliminary semiconductor chip modules Ml.

Then, when the preliminary semiconductor chip module M1 has passed the test, the procedure returns to the process for stacking an additional semiconductor chip. While not shown, in the case where the preliminary semiconductor chip module M1 has not passed the test, a reject mark may be formed on the corresponding preliminary semiconductor chip module M1 so that an additional semiconductor chip is not stacked any more.

Referring to FIG. 6D, by repeating the step of stacking an additional semiconductor chip 20a as shown in FIG. 6B and the step of performing a test as shown in FIG. 6C until a desired number of additional semiconductor chips 20a-c are stacked, a semiconductor chip module M with a desired shape is finally formed. The embodiment shown in the drawings illustrates a case in which three additional semiconductor chips 20a-c are stacked.

Referring to FIG. 6E, with the probe needles or sockets 60 of the test equipment brought into contact with the bonding pads 110 of the unselected semiconductor chip 100B, the semiconductor chip module M is tested by applying a test signal from the test equipment to the bonding pads 110 of the unselected semiconductor chip 100B.

The test signal applied to the bonding pads 110 of the unselected semiconductor chip 100B is loaded on the connection wiring line 300. The test signal includes the identity information of the semiconductor chip 100A included in the semiconductor chip module M. The semiconductor chips on the semiconductor wafer 10 compare the identity information included in the test signal with their identity information, and electrically connect the connection wiring line 300 with bonding pads 110 of a semiconductor chip when the identity information of the control signal matches the identity information of the semiconductor chip. Thereafter, the test signal is transmitted to the through-silicon vias 21 which are connected to the bonding pads 110. Accordingly, the semiconductor chip module M to be tested may be selectively tested among a plurality of semiconductor chip modules M.

While not shown, in order to prevent a semiconductor chip module M having not passed the test from being used in the manufacture of a package, a reject mark may be formed on the corresponding semiconductor chip module M.

Referring to FIG. 6F, the semiconductor chip module M is individualized by sawing the semiconductor wafer 100 along scribe lanes 200.

Referring to FIG. 6G, the semiconductor chip module M having passed the test is mounted to a substrate 40 which is formed with connection pads 43 on an upper surface 41 thereof in such a manner that the through-silicon vias 21 are connected with the connection pads 43. A molding part 50 is formed to mold the upper surface 41 of the substrate 40 including the semiconductor chip module M. By mounting external connection terminals 60 such as solder balls to ball lands 44 which are formed on a lower surface 42 of the substrate 40, a stack package is completed. Reference numeral 70 designates connection members which electrically connect the through-silicon vias 21 of the semiconductor chip module M with the connection pads 43 of the substrate 40.

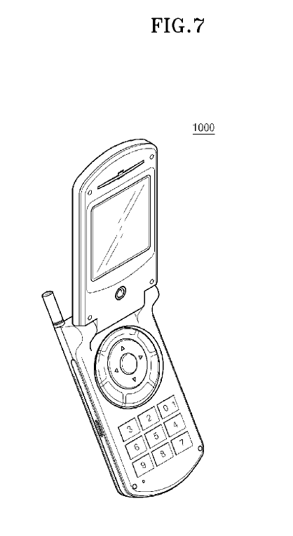

FIG. 7 is a perspective view illustrating an electronic apparatus having the stack package manufactured using the semiconductor wafer according to the present invention.

Referring to FIG. 7, the stack package according to an embodiment of the present invention may be applied to an electronic apparatus 1000 such as a portable phone. Since the stack package according to an embodiment of the present invention is excellent in terms of reliability, these stacked packages are advantageous in preventing an occurrence of a failure in the electronic apparatus 1000. The electronic apparatus 1000 is not limited to the portable phone shown in FIG. 7, and may include various electronic appliances, for example, such as a mobile electronic appliance, a laptop computer, a notebook computer, a portable multimedia player (PMP), an MP3 player, a camcorder, a web tablet, a wireless phone, a navigator, a personal digital assistant (PDA), and so forth.

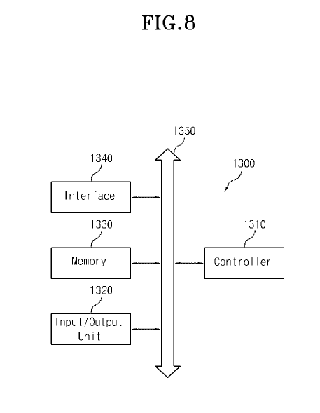

FIG. 8 is a block diagram showing an example of an electronic apparatus having a stack package manufactured using a semiconductor wafer according to the present invention.

Referring to FIG. 8, an electronic system 1300 may include a controller 1310, an input/output unit 1320, and a memory 1330. The controller 1310, the input/output unit 1320 and the memory 1330 may be coupled with one another through a bus 1350. The bus 1350 serves as a path through which data moves. For example, the controller 1310 may include at least any one of at least one microprocessor, at least one digital signal processor, at least one microcontroller, and logic devices capable of performing the same functions as these components. The controller 1310 and the memory 1330 may include the stack package according to the present invention. The input/output unit 1320 may include at least one selected among a keypad, a keyboard, a display device, and so forth. The memory 1330 is a device for storing data. The memory 1330 may store data and/or commands to be executed by the controller 1310, and the likes. The memory 1330 may include a volatile memory device and/or a nonvolatile memory device. Otherwise, the memory 1330 may be constituted by a flash memory. For example, a flash memory to which the technology of the present invention is applied may be mounted to an information processing system such as a mobile terminal or a desktop computer. The flash memory may be constituted by a Solide state derive (SSD). In this case, the electronic system 1300 may stably store a large amount of data in a flash memory system. The electronic system 1300 may further include an interface 1340 configured to transmit and receive data to and from a communication network. The interface 1340 may be a wired or wireless type. For example, the interface 1340 may include an antenna or a wired or wireless transceiver. Further, while not shown, a person skilled in the art will readily appreciate that the electronic system 1300 may be additionally provided with an application chipset, a camera image processor (CIP), an input/output unit, etc.

As is apparent from the above descriptions, in embodiments of the present invention, since semiconductor chips formed on a semiconductor wafer are electrically connected with one another through connection wiring lines, it is possible to test a semiconductor chip module which is stacked over another semiconductor chip by the medium of through-silicon vias, by applying a test signal to a semiconductor chip which is not used, that is an bad quality semiconductor chip. Therefore, since a physical stress is not applied to the semiconductor chip module when performing a test, it is possible to prevent a failure from occurring in the semiconductor chip module. Moreover, because a test may be performed by stacking semiconductor chips one by one, it is possible to prevent stacking any more semiconductor chips once a failure is detected in a stack, thereby a waste of a semiconductor chips may be avoided.

Although specific embodiments of the present invention have been described for illustrative purposes, those skilled in the art will appreciate that various modifications, additions and substitutions are possible, without departing from the scope and the spirit of the invention as disclosed in the accompanying claims.

What is claimed is:

1. A semiconductor wafer comprising:
a plurality of semiconductor chips having bonding pads; and
a connection wiring line coupling the plurality of semiconductor chips such that a test signal, which is inputted through bonding pads of an arbitrary semiconductor chip among the plurality of semiconductor chips, is transmitted to bonding pads of other semiconductor chips among the plurality of semiconductor chips.

2. The semiconductor wafer according to claim 1, further comprising:
scribe lanes formed between the semiconductor chips and dividing the plurality of semiconductor chips from one another.

3. The semiconductor wafer according to claim 2, wherein the connection wiring line extends across the scribe lanes and is cut when cutting along the scribe lanes.

4. The semiconductor wafer according to claim 1, wherein each of the plurality of semiconductor chips includes a control module associated with a semiconductor chip, where the control module is coupled with the connection wiring line and bonding pads of the semiconductor chip and which transmits a test signal of the connection wiring line to the bonding pads.

5. The semiconductor wafer according to claim 4, wherein the control module comprises:
a storage unit configured to store identity information of the semiconductor chip;
a comparison unit configured to compare identity information included in the test signal and the identity information stored in the storage unit, and output an enable signal when the identity information included in the test signal matches the identity information stored in the storage unit; and
a switching unit configured to be enabled by the enable signal and transmit the test signal of the connection wiring line to the bonding pads.

6. The semiconductor wafer according to claim 5, wherein the identity information is an identification code where each semiconductor chip has an assigned identity code.

7. The semiconductor wafer according to claim 4, wherein the control module comprises:
a counter configured to generate comparison coordinate values;
a comparison unit configured to compare coordinate values included in the test signal and the comparison coordinate values outputted from the counter, and output an enable signal when the coordinate value included in the test signal corresponds with the coordinate value outputted from the counter; and
a switching unit configured to be enabled by the enable signal and transmit the test signal to bonding pads of the semiconductor chip.

8. The semiconductor wafer according to claim 7, wherein counters of each of the plurality of semiconductor chips generate different comparison coordinate values.

9. The semiconductor wafer according to claim 8, wherein the counters of respective semiconductor chips of the plurality of semiconductor chips generate different comparison coordinate values through generating comparison coordinate values by adding coordinate changing values to comparison coordinate values which are generated by counters of adjacent semiconductor chips.

10. A method for manufacturing a stack package, comprising:
forming a semiconductor wafer including a plurality of semiconductor chips each comprising bonding pads and a connection wiring line which couples semiconductor chips of the plurality of semiconductor chips with one another such that a test signal, which is inputted through bonding pads of an arbitrary semiconductor chip among the plurality of semiconductor chips, is transmitted to bonding pads of other semiconductor chips among the plurality of semiconductor chips;
selecting a semiconductor chip among the plurality of semiconductor chips formed on the semiconductor wafer;
forming a semiconductor chip module by stacking a plurality of additional semiconductor chips, formed with through-silicon vias, on the selected semiconductor chip such that bonding pads of the selected semiconductor chip are connected with the through-silicon vias of the additional semiconductor chips; and
testing the semiconductor chip module by applying a test signal to bonding pads of a semiconductor chip which is not the selected semiconductor chip.

11. The method according to claim 10, wherein selecting the semiconductor chip among the plurality of semiconductor chips further comprises testing each of the semiconductor chips on the semiconductor wafer and selecting a semiconductor chip which has passed the test.

12. The method according to claim 10, wherein forming the semiconductor chip module further comprises:
preparing a preliminary semiconductor chip module by stacking the additional semiconductor chip;
testing the preliminary semiconductor chip module by applying a signal to the bonding pads of the unselected semiconductor chip; and
returning to the action of stacking the additional semiconductor chip when the preliminary semiconductor chip has passed the action of testing.

13. The method according to claim 12, wherein, after testing the preliminary semiconductor chip, the method further comprises:
forming a reject mark on a preliminary semiconductor chip module which has not passed the action of testing so that an additional semiconductor chip is not stacked any more on the corresponding preliminary semiconductor chip module which has not passed the action of testing.

14. The method according to claim 10, wherein, after testing the semiconductor chip module, the method further comprises:
forming a reject mark on a semiconductor chip module which has not passed the testing so that the corresponding semiconductor chip is not used.

15. The method according to claim 10, wherein, after testing of semiconductor chip module, the method further comprises:
individualizing the semiconductor chip module by sawing the semiconductor wafer along peripheries of the selected semiconductor chip.

16. The method according to claim 15, wherein, after individualizing the semiconductor chip module, the method further comprises:
mounting the semiconductor chip module having passed the testing, to a substrate formed with connection pads such that the through-silicon vias are connected with the connection pads; and
is forming a molding part to seal an upper surface of the substrate including the semiconductor chip module.
